(19) United States
(12) Patent Application Publication
(10) Pub. No.: US 2020/0035464 A1
(43) Pub. Date: Jan. 30, 2020

(54) COOLING STRUCTURE AND PARALLEL PLATE ETCHING APPARATUS

(71) Applicant: Tokyo Electron Limited, Tokyo (JP)

(72) Inventors: Keita KAMBARA, Miyagi (JP); Ryo SASAKI, Miyagi (JP)

(21) Appl. No.: 16/591,800

(22) Filed: Oct. 3, 2019

Related U.S. Application Data
(63) Continuation of application No. 14/963,465, filed on Dec. 9, 2015.

(30) Foreign Application Priority Data
Jan. 9, 2015 (JP) 2015-002997

(51) Int. Cl. H01J 37/32; F28F 13/00

(52) U.S. Cl. CPC H01J 37/32532; H01J 37/32724; H01J 37/32715; H01J 37/32009; F28F 13/00

(57) ABSTRACT

A cooling structure includes a cooling target member; a cooling plate including a cooling mechanism, the cooling plate being configured to cool the cooling target member; and a clamp configured to hold the cooling plate. The cooling plate includes a spherical portion having a spherical surface facing the cooling target member and having a center portion that bulges toward the cooling target member with respect to a peripheral edge portion, and a flat portion provided outside the spherical portion so that the spherical portion is thicker than the flat portion. The clamp is configured to apply at least a predetermined pressure only to the spherical portion through a surface of the cooling target member facing the cooling plate.

### CROSS-REFERENCE TO RELATED APPLICATIONS

The present application is a continuation application of U.S. patent application Ser. No. 14/963,465, which is based on and claims the benefit of priority to Japanese Patent Application No. 2015-002997 filed on Jan. 9, 2015, the entire contents of which are hereby incorporated by reference.

### BACKGROUND OF THE INVENTION

### 1. Field of the Invention

The present invention relates to a cooling structure and a parallel plate etching apparatus.

### 2. Description of the Related Art

Parallel plate etching apparatuses have an upper electrode and a lower electrode that are arranged to face each other within a chamber.

Parallel plate etching apparatuses are configured to generate a plasma between the upper and lower electrodes and perform an etching process on a substrate using the generated plasma. During such etching process, the temperature of the electrodes increases due to heat input from the plasma. Thus, a cooling plate is arranged to be in contact with an electrode such that the cooling plate may extract heat from the electrode to promote heat loss of the electrode.

However, as the electrode is consumed by a processing gas such that the thickness of the electrode is reduced and the rigidity of the electrode decreases, the electrode may be deformed to thereby cause a decrease in the contact force between the electrode and the cooling plate. As a result, the temperature distribution of the electrode may become non-uniform, and etching characteristics may be degraded. Also, in a case where gas holes are formed in the electrode, the gas holes may be enlarged over time to cause a further reduction in the contact force between the electrode and the cooling plate, and in turn, further variations may occur in the temperature distribution of the electrode.

To counter such problems, the thickness of the electrode may be increased to reduce deformation of the electrode. However, even when such measures are implemented, as the thickness of the electrode changes over time, variations may occur in the contact force between the electrode and the cooling plate at a center portion and a peripheral portion of the electrode, and as a result, the temperature distribution of the electrode may become non-uniform.

In view of the above, a technique has been proposed for making the temperature distribution of an electrode cover uniform by arranging the surface of the cooling plate into a convex shape (see e.g., Japanese Laid-Open Patent Publication No. H3-82022)

However, according to the above technique, an outer edge portion of the cooling plate is clamped to the electrode cover. Thus, the contact force between the cooling plate and the electrode cover is determined not only by the convex shape of the surface of the cooling plate but also the clamping force that clamps the cooling plate to the electrode cover. If a center portion and an edge portion of the electrode cover are held in contact with the cooling plate at varying contact forces, the temperature distribution of the electrode becomes non-uniform.

### SUMMARY OF THE INVENTION

An aspect of the present invention is directed to suitably arranging a cooling target member to be in contact with a cooling plate such that the cooling target member may have a uniform temperature distribution.

According to one embodiment of the present invention, a cooling structure is provided that includes a cooling target member, a cooling plate including a cooling mechanism and being configured to cool the cooling target member, and a clamp configured to hold the cooling target member to the cooling plate at an outer periphery of the cooling plate. The cooling plate includes a surface facing the cooling target member that is arranged into a spherical shape having a center portion that bulges toward the cooling target member with respect to a peripheral edge portion. The cooling target member includes a surface facing the cooling plate to which at least a predetermined pressure is applied.

### BRIEF DESCRIPTION OF THE DRAWINGS

FIG. 1 is a longitudinal cross-sectional view of a parallel plate etching apparatus according to an embodiment of the present invention;

FIG. 2 is a diagram illustrating temporal changes of a cooling plate according to an embodiment of the present invention (spherical) and a cooling plate according to a comparative example (flat);

FIG. 3 is a diagram illustrating an exemplary configuration of a cooling structure according to an embodiment of the present invention;

FIG. 4 is a diagram illustrating the relationship between the thermal resistance and the in-plane pressure of cooling plates according embodiments of the present invention; and

FIG. 5 is a diagram illustrating center/edge temperature differences of a cooling plate according to an embodiment of the present invention (spherical) and a cooling plate according to a comparative example (flat).

### DESCRIPTION OF THE PREFERRED EMBODIMENTS

In the following, embodiments of the present invention will be described with reference to the accompanying drawings. Note that in the following descriptions and accompanying drawings, elements having substantially the same functions or features may be given the same reference numerals and overlapping descriptions thereof may be omitted.

[Overall Configuration of Parallel Plate Etching Apparatus]

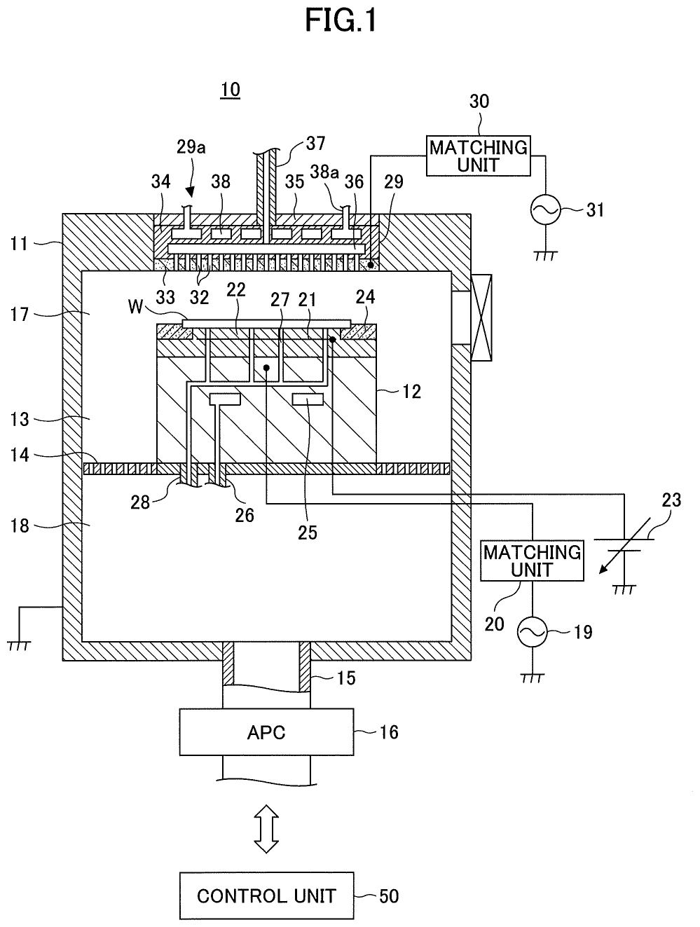

First, an overall configuration of a parallel plate etching apparatus 10 according to an embodiment of the present invention is described with reference to FIG. 1. The parallel plate etching apparatus 10 includes a cylindrical chamber 11 made of aluminum or the like that is capable of being sealed. The chamber 11 is connected to a ground potential. A mounting table 12 made of a conductive material such as aluminum is provided within the chamber 11. The mounting table 12 is a cylindrical column that holds a semiconductor wafer (also referred to as “wafer W” hereinafter). The mounting table 12 also acts as a lower electrode.

An exhaust path 13 is formed between a side wall of the chamber 11 and a side face of the mounting table 12. The exhaust path 13 is for discharging gas toward the upper side of the mounting table 12 to the exterior of the chamber 11. An exhaust plate 14 is arranged at an intermediate section of the exhaust path 13. The exhaust plate 14 is a plate-like member having multiple holes and acts as a partition plate that partitions the chamber 11 into an upper portion and a lower portion. The upper portion of the chamber 11 partitioned by the exhaust plate 14 corresponds to a reaction chamber 17 in which plasma etching is performed. The lower portion of the chamber 11 corresponds to an exhaust chamber (manifold) 18. An exhaust pipe 15 for discharging gas within the chamber 11 to the exterior is connected to the exhaust chamber 18. The exhaust plate 14 prevents a plasma generated in the reaction chamber 17 from leaking into the exhaust chamber 18 by trapping or reflecting the generated plasma. The exhaust pipe 15 is connected to an exhaust system (not shown) via an APC (Adaptive Pressure Control: Automatic Pressure Control) valve 16. The exhaust system reduces the pressure within the chamber 11 to maintain the interior of the chamber 11 to a predetermined degree of vacuum.

A first high frequency power source 19 is connected to the mounting table 12 via a matching unit 20. For example, the first high frequency power source 19 may supply a high frequency bias power having a frequency within a range of 400 kHz to 13.56 MHz (also referred to as “high frequency bias power LF” hereinafter) to the mounting table 12. The matching unit 20 is configured to suppress the reflection of the high frequency bias power LF from the mounting table 12 and maximize the supply efficiency of the high frequency bias power LF to the table 12.

An electrostatic chuck 22 having an electrostatic electrode plate 21 arranged in its interior is provided at an upper portion of the mounting table 12. The electrostatic chuck 22 may include an upper circular plate member having a smaller diameter than a lower circular plate member arranged on top of the lower circular plate member. The electrostatic chuck 22 may be made of aluminum and have an upper surface sprayed with a ceramic material or the like. When mounting a wafer W on the mounting table 12, the wafer W is placed on the upper circular plate member of the electrostatic chuck 22.

Also, a DC power source 23 is connected to the electrostatic electrode plate 21. When a positive DC voltage (also referred to as “DC voltage HV” hereinafter) is applied to the electrostatic electrode plate 21, a negative potential is generated at a rear face of the wafer W (face toward the electrostatic chuck 22), and a potential difference is created between the electrostatic electrode plate 21 and the rear face of the wafer W. The wafer W is electrostatically attracted and held onto the upper circular plate member of the electrostatic chuck 22 by a Coulomb force or a Johnson-Rahbek force generated by the above potential difference.

Also, an annular focus ring 24 is arranged on the electrostatic chuck 22 to surround a peripheral edge portion of the wafer W. The focus ring 24 may be made of a conductive material such as silicon. The focus ring 24 is configured to focus the plasma within the reaction chamber 17 toward a surface of the wafer W to thereby improve efficiency of an etching process.

Also, an annular coolant chamber 25 may be arranged to extend along a circumferential direction within the mounting table 12, for example. A low temperature coolant such as cooling water or Galden (registered trademark) may be supplied from a chiller unit (not shown) to the coolant chamber 25 via a coolant pipe 26 and circulated within the coolant chamber 25. The mounting table 12 that has been cooled by the low temperature coolant cools the wafer W and the focus ring 24 via the electrostatic chuck 22.

A plurality of heat transfer gas supply holes 27 are formed on a surface of the upper circular plate member of the electrostatic chuck 22 on which the wafer W is electrostatically attracted (attracting surface). A heat transfer gas such as helium (He) may be supplied to the plurality of heat transfer gas supply holes 27 via a heat transfer gas supply line 28. The heat transfer gas is supplied to a gap between the attracting surface of the electrostatic chuck 22 and the rear face of the wafer W via the heat transfer gas supply holes 27. The heat transfer gas supplied to the gap transfers heat of the wafer W to the electrostatic chuck 22.

A shower head 29 is arranged at a ceiling portion of the chamber 11 to face the mounting table 12. A second high frequency power source 31 is connected to the showerhead 29 via a matching unit 30. The second high frequency power source 31 may supply a high frequency power for plasma excitation having a frequency of around 40 MHz, for example, (also referred to as “high frequency excitation power HF” hereinafter) to the shower head 29. In this way, the shower head 29 may also act as an upper electrode. The matching unit 30 is configured to suppress reflection of the high frequency excitation power HF from the shower head 29 to thereby maximize the supply efficiency of the high frequency excitation power HF to the shower head 29. Note that in some embodiments, the high frequency excitation power HF may be applied to the mounting table 12.

The shower head 29 includes a ceiling electrode plate 33 having a plurality of gas holes 32, a cooling plate 34 for detachably suspending the ceiling electrode plate 33, and a lid 35 that covers the cooling plate 34. Also, a buffer chamber 36 is provided within the cooling plate 34, and the buffer chamber 36 is connected to a gas introducing pipe 37. The shower head 29 is configured such that the gas supplied from the gas introducing pipe 37 into the buffer chamber 36 is supplied to the reaction chamber 17 via the plurality of gas holes 32.

The shower head 29 is detachable with respect to the chamber 11 and also functions as a lid of the chamber 11. When the showerhead 29 is detached from the chamber 11, an operator may directly touch the walls and components of the chamber 11. In this way, the operator may be able to clean the surfaces of the walls and components of the chamber 11 and remove extraneous matter adhered to the wall of the chamber 11, for example.

In the parallel plate etching apparatus 10, the high frequency bias power LF is applied to the mounting table 12, and the high frequency excitation power HF is applied to the shower head 29 within the reaction chamber 17. By supplying the high frequency bias power LF and the high frequency excitation power HF to the reaction chamber 17, a plasma may be generated from the gas supplied from the shower head 29, and etching may be performed on the wafer W by the generated plasma. Note that operations for supplying the gas and the high frequency power to the parallel plate etching apparatus 10 are controlled by a control unit 50. A CPU of the control unit 50 executes plasma etching on the wafer W in accordance with a relevant recipe that sets out the procedures of the etching process.

[Cooling Structure]

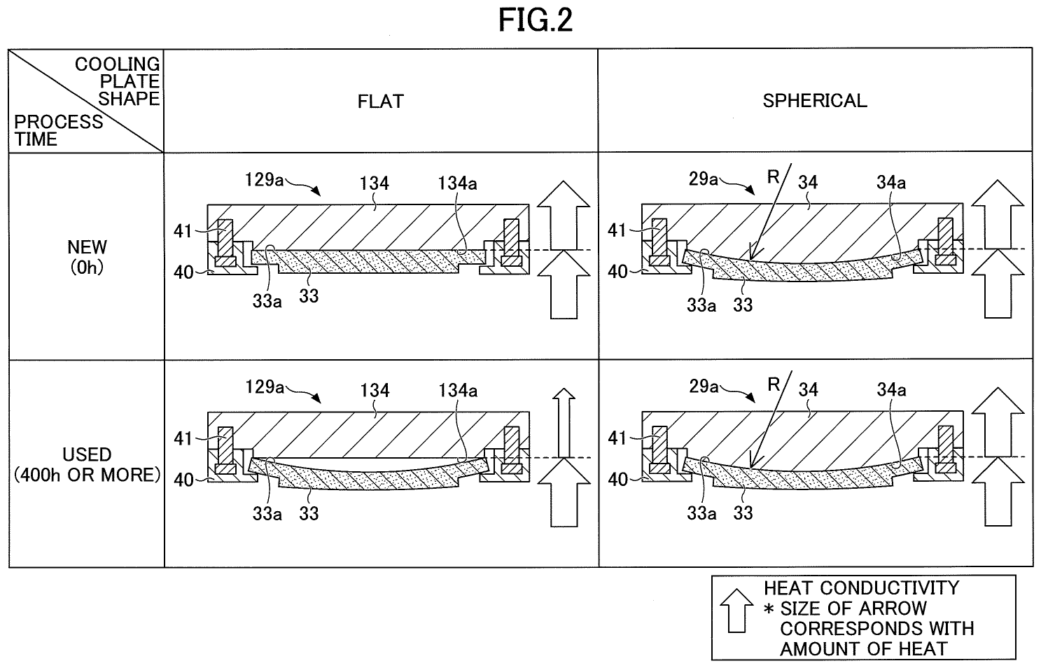

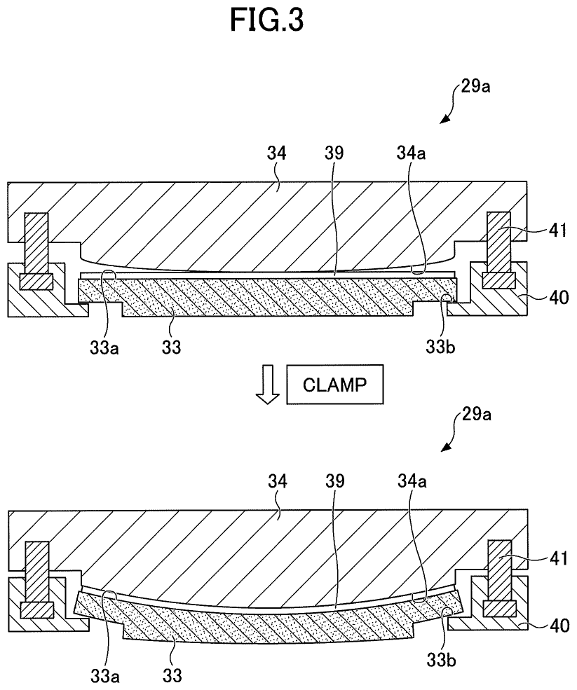

In the following, exemplary configurations of a cooling structure arranged within the shower head 29 according to embodiments of the present invention will be described with reference to FIGS. 2 and 3. FIG. 2 illustrates temporary changes of a cooling plate according to an embodiment of the present invention (spherical) and a cooling plate according to a comparative example (flat).

On the right side of FIG. 2, a cooling structure 29a according to the present embodiment (with the cooling plate 34 having a surface 34a facing a ceiling electrode plate 33 arranged into a spherical shape) is illustrated. On the left side of FIG. 2, a cooling structure 129a according to the comparative example (with a cooling plate 134 having a surface 134a facing the ceiling electrode plate 33 arranged into a flat shape) is illustrated.

The cooling structure 29a according to the present embodiment includes the ceiling electrode plate 33, the cooling plate 34 for cooling the ceiling electrode plate 33, and a clamp 40 for clamping the ceiling electrode plate 33 to the cooling plate 34 at an outer periphery of the cooling plate 34. The ceiling electrode plate 33 is made of a conductive material such as silicon. The cooling plate 34 and the clamp 40 are made of a metal such as aluminum.

The surface 34a of the cooling plate 34 facing the ceiling electrode plate 33 is arranged into a spherical shape having a center portion (also referred to as “center” hereinafter) that bulges toward the ceiling electrode plate 33 with respect to a peripheral edge portion (also referred to as “edge” hereinafter).

The clamp 40 holds an outer peripheral edge portion of the ceiling electrode plate 33, and in such a state, the clamp 40 is fixed to the cooling plate 34 by a screw 41. In this way, at least a predetermined pressure may be applied to a surface 33a of the ceiling electrode plate 33 facing the cooling plate 34. The predetermined pressure is preferably arranged to be 0.1 MPa based on experimental results as described below. By controlling the pressure applied to the surface 33a to at least the above value, the contact between the ceiling electrode plate 33 and the cooling plate 34 may be maintained uniform both at the center and the edge of the ceiling electrode plate 33 in a case where the cooling structure 29a is new (before an etching process is performed on a wafer W) as well as a case where the cooling structure 29a is used (after the etching process is performed for a predetermined time period of about 400 hours). As a result, even when the ceiling electrode plate 33 has been consumed (used) to the extent it needs to be replaced, heat conductivity from the ceiling electrode plate 33 to the cooling plate 34 may be maintained. Thus, variations in the temperature distribution of the ceiling electrode plate 33 at the center and the edge may be suppressed such that a uniform temperature distribution may be achieved and good etching characteristics may be obtained.

On the other hand, the cooling structure 129a according to the comparative example as illustrated at the left side of FIG. 2 differs from the cooling structure 29a according to the present embodiment at the right side of FIG. 2 in that the surface 134a of the cooling plate 134 facing the ceiling electrode plate 33 is arranged into a flat shape. Also, in the cooling structure 129a according to the comparative example, the pressure applied to the surface 33a of the ceiling electrode plate 33 facing the cooling plate 134 is not controlled to be at least the predetermined pressure.

Thus, in the cooling structure 129a according to the comparative example, after an etching process is performed for about 400 hours, the ceiling electrode plate 33 may be reduced in thickness by being consumed by the processing gas, and the rigidity of the ceiling electrode plate 33 may decrease. As a result, the used ceiling electrode plate 33 may be deformed, and the contact force between the ceiling electrode plate 33 and the cooling plate 134 may be weakened particularly at the center portion. In turn, heat conductivity from the ceiling electrode plate 33 to the cooling plate 34 may be degraded, and the temperature distribution of the ceiling electrode plate 33 may become non-uniform to thereby cause a degradation of the etching characteristics.

The cooling plate 34 according to the present embodiment has the surface 34a facing the ceiling electrode plate 33 arranged into a spherical surface. In this way, a decrease in uniformity of the temperature distribution of the ceiling electrode plate 33 due to temporal changes may be suppressed in the cooling structure 29a according to the present embodiment. Further, in the cooling structure 29a according to the present embodiment, the in-plane pressure of the surface 33a of the ceiling electrode plate 33 facing the cooling plate 34 is controlled to be at least a predetermined pressure. In this way, a decrease in uniformity of the temperature distribution of the ceiling electrode plate 33 due to temporal changes may be further suppressed. As a result, desirable etching characteristics may be obtained even when the ceiling electrode plate 33 is consumed (used), for example.

Note that although the cooling structure 29a according to the present embodiment is arranged within the shower head 29, a cooling structure according to the present invention is not limited thereto. Also, the ceiling electrode plate 33 is one illustrative example of a cooling target member. That is, a cooling target member according to the present invention is not limited to an electrode but may be any member that needs to be cooled by a cooling plate and is adhered to the cooling plate by a clamp. Also, although the cooling structure 29a according to the present embodiment is arranged in the parallel plate etching apparatus 10, the cooling structure according to the present invention is not limited to being applied to a parallel plate etching apparatus but may be applied to any apparatus having a cooling target member that is required to have a uniform temperature distribution.

In the following, another exemplary configuration of the cooling structure 29a according to an embodiment of the present invention will be described with reference to FIG. 3. FIG. 3 illustrates another configuration of the cooling structure 29a according to the present embodiment. The configuration of the cooling structure 29a illustrated in FIG. 3 differs from that illustrated in FIG. 2 in that a heat transfer sheet 39 is inserted between the cooling plate 34 and the ceiling electrode plate 33. The heat transfer sheet 39 may be made of an insulator such as a polymer sheet. In this way, adhesion between the surface 33a of the ceiling electrode plate 33 and the surface 34a of the cooling plate 34 may be improved. As a result, uniformity of the temperature distribution of the ceiling electrode plate 33 may be further improved, and more favorable etching characteristics may be stably obtained, for example.

[Heat Transfer Sheet and Thermal Resistance]

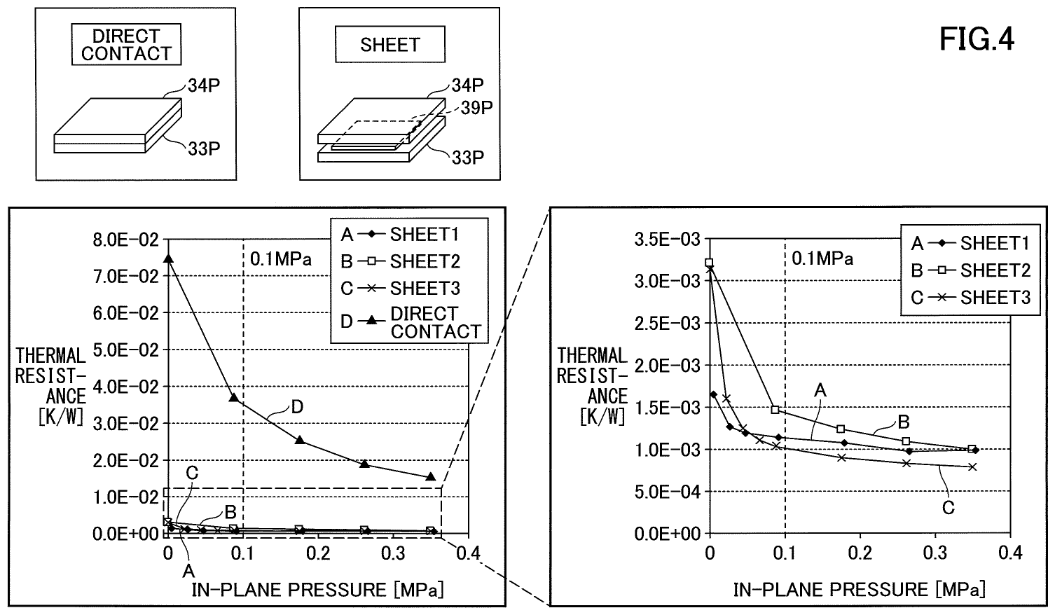

For example, FIG. 4 illustrates experimental results indicating the relationship between the thermal resistance and the in-plane pressure of the ceiling electrode plate 33 obtained from various experimental samples. Curve D in FIG. 4 represents experimental results indicating the relationship between the thermal resistance and the in-plane pressure of the ceiling electrode plate 33 in a case where a sample 33P of the ceiling electrode plate 33 is in direct contact with a sample 34P of the cooling plate 34 according to the present embodiment. Also, curves A-C in FIG. 4 represent experimental results indicating the relationship between the thermal resistance and the in-plane pressure of the ceiling electrode plate 33 in cases where three different types of heat transfer sheets (sheets 1-3) are interposed between the sample 33P of the ceiling electrode plate 33 and the sample 34P of the cooling plate 34 according to the present embodiment.

In this experiment, the thermal resistance of the sample 33P of the ceiling electrode plate 33 was measured in vacuum taking into account the fact that the chamber 11 of the parallel plate etching apparatus 10 in which the cooling structure 29a is used would be in a state of vacuum. It can be appreciated from the experimental results that in all of the curves A-D, variations in thermal resistance can be reduced when the in-plane pressure at the surface 33a of the ceiling electrode plate 33 facing the cooling plate 34 is at least 0.1 MPa, and heat conductivity of the ceiling electrode plate 33 to the cooling plate 34 may be stabilized. In other words, when a pressure of at least 0.1 MPa is applied to the surface 33a of the ceiling electrode plate 33 facing the cooling plate 34, variations in the thermal resistance of the ceiling electrode plate 33 may be reduced and the ceiling electrode plate 33 may be in a thermally stabilized state. Also, it can be appreciated that in the case where a heat transfer sheet is inserted between the ceiling electrode plate 33 and the cooling plate 34, the thermal resistance may be at least two times lower than the case where no heat transfer sheet is inserted, and heat conductivity from the ceiling electrode plate 33 to the cooling plate 34 may be improved.

[Optimization of Clamping Force and Torque]

A radius R of the spherical surface 34a of the cooling plate 34 of the cooling structure 29a according to the present embodiment may be any value within a range of 84 m to 120 m. In the present embodiment, as illustrated in FIG. 3, the torque holding the ceiling electrode plate 33 to the cooling plate 34 at the outer periphery of the cooling plate 34 is optimized based on the number of screws 41 and the clamping force of the clamp 40. In this way, a pressure of at least 0.1 MPa is preferably applied to the surface 33a of the ceiling electrode plate 33 facing the cooling plate 34.

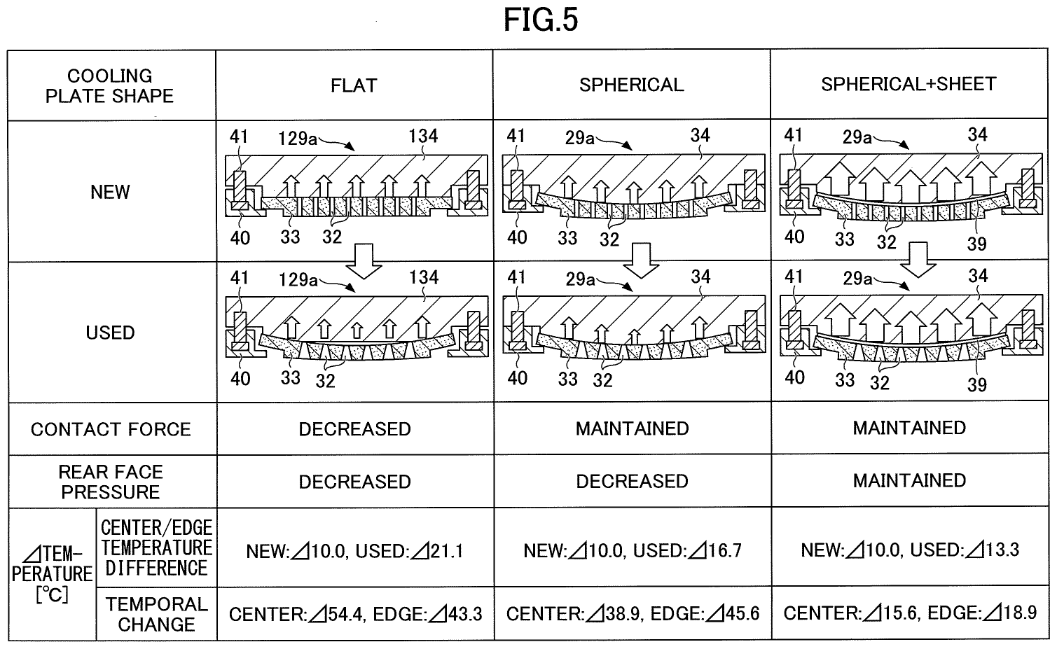

For example, FIG. 5 is a table indicating experimental results of measuring the contact force (torque), center/edge temperature differences, and temporal changes in the temperature of various cooling structures. In the center of the table of FIG. 5, the torque generated by the clamp 40, the center/edge temperature differences, and the temporal changes in the temperature of the cooling structure 29a according to the present embodiment having the cooling plate 34 (spherical) arranged in direct contact with the ceiling electrode plate 33 are shown.

Also, on the right side of the table of FIG. 5, the torque generated by the clamp 40, the center/edge temperature differences, and the temporal changes in the temperature of the cooling structure 29a according to the present embodiment having a heat transfer sheet interposed between the cooling plate 34 (spherical) and the ceiling electrode plate 33 are shown.

Also, on the left side of the table of FIG. 5, the torque generated by the clamp 40, the center/edge temperature differences, and the temporal changes in the temperature of the cooling structure 129a according to the comparative example (with the cooling plate 134 having a flat surface) are shown.

In this experiment, temporal changes in the temperature distribution of the ceiling electrode plate 33 from the time the ceiling electrode plate 33 was new to the time the ceiling electrode plate 33 was consumed (used for about 400 hours for etching) were analyzed by measuring the temperature difference between the center and the edge of the ceiling electrode plate 33.

According to the experimental results, in the cooling structure 129a according to the comparative example, the contact force between the ceiling electrode plate 33 and the cooling plate 34 and the rear face (in-plane) pressure of the ceiling electrode plate 33 “decreased” from the time the ceiling electrode plate 33 was new to the time the ceiling electrode plate 33 was consumed (used). Also, the temperature difference between the center and the edge of the ceiling electrode plate 33 was “10.0” degrees (° C.) in the case where the ceiling electrode plate 33 was new, and “21.1” degrees (° C.) in the case where the ceiling electrode plate 33 was consumed (used). That is, the temperature difference increased by more than two times the temperature difference at the time the ceiling electrode plate 33 was new. As can be appreciated, in the cooling structure 129a according to the comparative example, the temperature distribution of the ceiling electrode plate 33 became more uneven when the ceiling electrode plate 33 was consumed (used) as compared to when the ceiling electrode plate 33 was new. In particular, the temperature difference between the time the ceiling electrode plate 33 was new and the time the ceiling electrode plate 33 was consumed was “54.4” degrees (° C.) at the center, and “43.3” degrees (° C.) at the edge, indicating that the temperature difference was larger at the center of the ceiling electrode plate 33. It can be appreciated from the above that when the ceiling electrode plate 33 is consumed, the contact between the cooling plate 134 and the ceiling electrode plate 33 is weakened even more at the center as compared to the edge. As a result, heat conductivity from the ceiling electrode plate 33 to the cooling plate 134 is degraded, and the temperature distribution of the ceiling electrode plate 33 becomes non-uniform.

On the other hand, in the cooling structure 29a according to the present embodiment, in the case where a heat transfer sheet was interposed, both the contact force between the cooling plate 34 and the ceiling electrode plate 33 and the rear face (in-plane) pressure of the ceiling electrode plate 33 were “maintained” from the time the ceiling electrode plate 33 was new to the time the ceiling electrode plate 33 was consumed. In the case where no heat transfer sheet was interposed, the contact force between the cooling plate 34 and the ceiling electrode plate 33 was “maintained”, while the rear face (in-plane) pressure of the ceiling electrode plate 33 “decreased”. In the cooling structure 29a according to the present embodiment, the temperature difference between the center and the edge of the ceiling electrode plate 33 when the ceiling electrode plate 33 was consumed was “13.3” degrees (° C.) in the case where a heat transfer sheet was interposed, and “16.7” degrees (° C.) in the case where no heat transfer sheet was interposed. That is, the above center/edge temperature differences in the consumed ceiling electrode plate 33 arranged in the cooling structure 29a according to the present embodiment are smaller than the center/edge temperature difference “21.1” degrees (° C.) in the consumed ceiling electrode plate 33 arranged in the cooling structure 129a according to the comparative example. It can be appreciated from the above that in the cooling structure 29a according to the present embodiment, uniformity in the temperature distribution of the ceiling electrode plate 33 may be maintained even after the ceiling electrode plate 33 is consumed.

Specifically, in the case where a heat transfer sheet was not interposed in the cooling structure 29a according to the present embodiment, the temperature difference between the time the ceiling electrode plate 33 was new and the time the ceiling electrode plate 33 was consumed was “38.9” degrees (° C.) at the center, and “45.6” degrees (° C.) at the edge, indicating that the temperature difference is smaller at the center of the ceiling electrode plate 33.

In the case where a heat transfer sheet was interposed in the cooling structure 29a according to the present embodiment, the temperature difference between the time the ceiling electrode plate 33 was new and the time the ceiling electrode plate 33 was consumed was “15.6” degrees (° C.) at the center, and “18.9” degrees (° C.) at the edge, indicating that the temperature difference was smaller at the center of the ceiling electrode plate 33. Also, it can be appreciated that in the case where the heat transfer sheet was interposed, the temperature difference between the center and the edge of the ceiling electrode plate 33 could be minimized, and the impact of temporal changes on the heat conductivity of the ceiling electrode plate 33 could be minimized.

In the cooling structure 29a according to the present embodiment, the surface 34a of the cooling plate 34 facing the ceiling electrode plate 33 is arranged into a spherical shape having a center portion that bulges toward the ceiling electrode plate 33 with respect to a peripheral portion. Also, in the cooling structure 29a according to the present embodiment, at least a predetermined pressure is applied to the surface 33a of the ceiling electrode plate 33 facing the cooling plate 34. Specifically, a torque applied to the surface 33a is controlled by the clamp 40 and the number of screws 41, and when twelve (12) screws 41 are used, for example, the clamping force is adjusted such that the in-plane pressures at the center and the edge of the ceiling electrode plate 33 are at least 0.1 MPa.

By arranging the cooling structure 29a according to the present embodiment to have such a configuration, a pressure of at least 0.1 MPa may be applied to the surface 33a of the ceiling electrode plate 33 even when the gas holes are enlarged over time due to continued use, for example. In this way, the ceiling electrode plate 33 may remain in contact with the spherical surface 34a of the cooling plate 34 and heat conductivity of the ceiling electrode plate 33 may not be degraded even after the ceiling electrode plate 33 has been consumed. Further, in the case where the heat transfer sheet 39 is inserted between the cooling plate 34 and the ceiling electrode plate 33, adhesion of the ceiling electrode plate 33 to the cooling plate 34 may be strengthened as compared with the case where the heat transfer sheet 39 is not inserted. In this way, heat from the ceiling electrode plate 33 may be more effectively extracted by the cooling plate 34.

As described above, in the cooling structure 29a according to the present embodiment, the surface 34a of the cooling plate 34 facing the ceiling electrode plate 33 has a spherical shape, and a predetermined pressure of at least 0.1 MPa is applied to the surface 33a of the ceiling electrode plate 33 facing the cooling plate 34. In this way, proper contact between the ceiling electrode plate 33 and the cooling plate 34 may be maintained, and uniformity in the temperature distribution of the ceiling electrode plate 33 may be maintained even after the ceiling electrode plate 33 is consumed.

Although a cooling structure and a parallel plate etching apparatus according to the present invention have been described above with respect to certain illustrative embodiments, the cooling structure and the parallel plate etching apparatus according to the present invention are not limited to the above embodiments, and various modifications and improvements may be made within the scope of the present invention. Also, features of the embodiments described above may be combined to the extent practicable.

For example, the cooling structure according to the present invention is not limited to being applied to a capacitively coupled plasma (CCP) etching apparatus but may also be implemented in other various types of semiconductor manufacturing apparatuses. Examples of other types of semiconductor manufacturing apparatuses include an inductively coupled plasma (ICP) processing apparatus, a helicon wave plasma (HWP) processing apparatus, an electron cyclotron resonance plasma (ECR) processing apparatus, and the like. The cooling structure according to the present invention may be used as a structure for cooling a cooling target member such as an electrode arranged within the above semiconductor manufacturing apparatuses, for example.

Also, a substrate that is subject to etching by the parallel plate etching apparatus according to the present invention is not limited to a semiconductor wafer but may be a large substrate for a flat panel display (FPD), an electroluminescence (EL) element, or a substrate for a solar battery, for example.

What is claimed is:

1. A cooling structure comprising:
a cooling target member;
a cooling plate including a cooling mechanism, the cooling plate being configured to cool the cooling target member; and
a clamp configured to hold the cooling plate;
wherein the cooling plate includes:
a spherical portion having a spherical surface facing the cooling target member and having a center portion that bulges toward the cooling target member with respect to a peripheral edge portion, and
a flat portion provided outside the spherical portion so that the spherical portion is thicker than the flat portion, and
wherein the clamp is configured to apply at least a predetermined pressure only to the spherical portion through a surface of the cooling target member facing the cooling plate.

2. The cooling structure according to claim 1, wherein the clamp is fixed to the flat portion.

3. The cooling structure according to claim 1, wherein the predetermined pressure is 0.1 MPa.

4. The cooling structure according to claim 1, wherein the cooling plate has a spherical shape with a radius of 84 m to 120 m.

5. The cooling structure according to claim 1, wherein
the cooling target member is an electrode; and
the cooling structure is arranged in a parallel plate etching apparatus configured to perform an etching process on a substrate.

6. The cooling structure according to claim 4, further comprising:
a heat transfer sheet that is inserted between the cooling plate and the electrode.

7. The cooling structure according to claim 4, wherein
the electrode includes the surface facing the cooling plate to which at least the predetermined pressure is applied before an etching process is performed on the substrate and after the etching process has been performed for a predetermined time period.

8. The cooling structure according to claim 5, wherein the heat transfer sheet is made of an insulator.

9. A parallel plate etching apparatus comprising:
a chamber in which a substrate is etched;
a cooling target member;
a cooling plate including a cooling mechanism, the cooling plate being configured to cool the cooling target member; and
a clamp configured to hold the cooling plate;
wherein the cooling plate includes:
a spherical portion having a spherical surface facing the cooling target member and having a center portion that bulges toward the cooling target member with respect to a peripheral edge portion, and
a flat portion provided outside the spherical portion so that the spherical portion is thicker than the flat portion, and
wherein the clamp is configured to apply at least a predetermined pressure only to the spherical portion through a surface of the cooling target member facing the cooling plate.

10. The cooling structure according to claim 1, wherein the cooling target member has a center portion that bulges toward a substrate.

11. The cooling structure according to claim 1, wherein the clamp is fixed to the cooling plate by a screw.

12. The cooling structure according to claim 11, wherein the clamp is configured to hold the cooling target member at an outermost peripheral portion of the cooling target member.
